(19) United States
(12) Patent Application Publication
(10) Pub. No.: US 2008/0273375 A1
(43) Pub. Date: Nov. 6, 2008

(54) INTEGRATED CIRCUIT HAVING A MAGNETIC DEVICE

(76) Inventors: Faiz Dahmani, Saint-Hilaire (FR); Chanro Park, Samois-sur-Seine (FR); Rainer Leuschner, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/743,449

(22) Filed: May 2, 2007

(51) Int. Cl. H01L 29/82; G11C 11/00; H01L 21/00

(52) U.S. Cl. 365/158; 257/421; 438/3; 257/E29.323; 257/E21.001

(57) ABSTRACT

An integrated circuit having a magnetic device is disclosed. In one embodiment, the integrated circuit includes a reference structure having a first blocking temperature. A storage structure is provided made of a ferromagnetic material. An antiferromagnetic structure is provided having a second blocking temperature lower than the first blocking temperature.

### BACKGROUND

Magnetic (or magneto-resistive) random access memory (MRAM) is a non-volatile memory technology that shows considerable promise for long-term data storage. Performing read and write operations on MRAM devices is much faster than performing read and write operations on conventional memory devices such as DRAM and Flash and order of magnitude faster than long-term storage device such as hard drives. A conventional magnetic memory element (also referred to as a tunneling magneto-resistive or TMR-device) includes a structure having ferromagnetic layers separated by a non-magnetic layer (barrier) and arranged into a magnetic tunnel junction (MTJ).

Digital information is stored and represented in the magnetic memory element as directions of magnetization vectors in the ferromagnetic layers. More specifically, the magnetic moment of one ferromagnetic layer is magnetically fixed or pinned and kept rigid (also referred to as “fixed layer”, “reference layer” or “hard layer”), while the magnetic moment of the other ferromagnetic layer (also referred to as “free layer” or “soft layer”) is free to be switched between the parallel (low resistance) and anti-parallel (high resistance) magnetization directions with respect to the fixed magnetization direction of the reference layer by application of electric currents, therein inducing a change in the cell resistance. The corresponding logic state (“0” or “1”) of the memory is hence defined by its resistance state (low or high), monitored by a small read current. Furthermore, a bit of data may be stored by “writing” into the storage layer via one or more conducting leads (bit and word lines). The write operation is typically accomplished via a write current that sets the orientation of the magnetization vector in the storage layer to a predetermined direction.

Conventionally, a fully functional MRAM memory is based on a 2D array of individual cells, which can be addressed individually. Conventionally, each memory cell combines a CMOS selection transistor with a magnetic tunnel junction and two line levels (bit lines and word lines). At read, a low power current pulse opens the transistor to address the selected memory cell. The cell resistance is measured by driving a current from the “word line” through the MTJ and compared to a reference cell located in the array. At write, the “word lines” and “bit lines”, arranged in cross-point architecture on each side of the MTJ, are energized by synchronized current pulses in order to generate a magnetic field on the addressed memory cell. The intensities of the pulses are chosen such that only the storage layer at the cross-point of the two lines (the so-called fully selected cell) can be switched, all other cells on any given line or column (the so-called half selected cells) being unable to switch.

According to “Stoner-Wohlfarth model” the magnetization in a particular element stays fixed in a certain orientation of the easy axis, as long as external fields applied to this element stay within the critical switching curve. The astroid behavior of this switching can be used to selectively switch a certain cell by superposing the magnetic fields generated by two metal lines, if the sum of the magnetic fields is high enough for switching while the single fields themselves are not (so that none of the other cells along each of the active metal lines are losing there current magnetization state). In the contrary, the astroid for the reference layer should cover a much wider field range so that only the information layer switches upon applying the magnetic fields generated by the metal lines. Conventionally, the field required to switch the reference layer is about ten times that needed for switching the storage layer. Conventionally, the Stoner-Wohlfarth astroid is measured as a function of the word and bit line current pulses. To prevent selection errors, this current has to be large enough to ensure switching of all selected cells, but low enough to prevent switching of half-selected cells. This defines the write window, which is primarily determined by the switching field distribution in the array.

MRAM devices to be fully competitive have to provide high density memories and the only way to reach this ultimate goal is to reduce the cell size to below 100-nm node. At this cell size, the write power will increase, due to the switching field being inversely proportional to particle size, the selection errors at write will increase, as the switching field distribution is expected to increase for these dimensions, the long-term stability of the data will be jeopardized, due to the increasing impact of thermal activation. Furthermore, a high tunneling magnetoresistance ratio (TMR) is also required to make the MRAM very attractive for the read operation in a very dense memory cell. The high TMR is of course important to obtaining a large signal from a memory cell, especially if a fast read operation is desired. Also required is a very low resistance-area (RA) product to reducing the critical current density needed to switch the storage layer.

What is needed in the art is to achieve high density MRAM cells with low switching current density and high read signal. In particular, what is needed in the art is to achieve sub-100 nm cell size with minimal power consumption.

For these and other reasons, there is a need for the present invention.

### SUMMARY

One or more embodiments provide an integrated circuit having a magnetic device. In one embodiment, the integrated circuit includes a reference structure having a first blocking temperature. A storage structure is provided made of a ferromagnetic material. An antiferromagnetic structure is provided having a second blocking temperature lower than the first blocking temperature.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

FIG. 1a is a schematic cross-sectional view illustrating one embodiment of an integrated circuit having a thermally assisted MTJ element.

FIG. 1b is a schematic diagram illustrating one embodiment of a selected storage cell of an MRAM memory array in an integrated circuit.

FIG. 2a is a diagram illustrating one embodiment of an ideal hysteresis loop for a pinned storage layer.

FIG. 2b is a diagram illustrating one embodiment of an ideal hysteresis loop for the produced exchange coupling layers.

FIG. 3a is a schematic cross-sectional view illustrating one embodiment of the stacking formation of an MTJ device.

FIG. 3b is a schematic diagram illustrating one embodiment of a selected storage cell of an MRAM memory array.

FIG. 4 is a graph illustrating an example of an hysteresis loop for an MTJ element at room temperature according to one embodiment.

FIG. 5 is a graph illustrating the exchange bias and the coercivity as a function of the different Argon deposition process conditions for IrMn according to one embodiment.

FIG. 6 is a diagram illustrating the dependency of the blocking temperature of IrMn on IrMn thickness at room temperature for two different argon flow process for a continuous MTJ film according to one embodiment.

FIG. 7a is a schematic cross-sectional view illustrating one embodiment of the stacking formation of an MTJ device.

FIG. 7b is a schematic diagram illustrating one embodiment of a selected storage cell of an MRAM memory array.

FIG. 8 is a graph illustrating an example of hysteresis loop of a 400×600 nm² patterned MTJ cell according to one embodiment, measured at room temperature for a bias voltage of −1350 millivolts (mV).

FIGS. 9A and 9B are schematic diagrams illustrating example embodiments of memory module systems.

FIG. 10 is a schematic diagram illustrating an example computing system according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

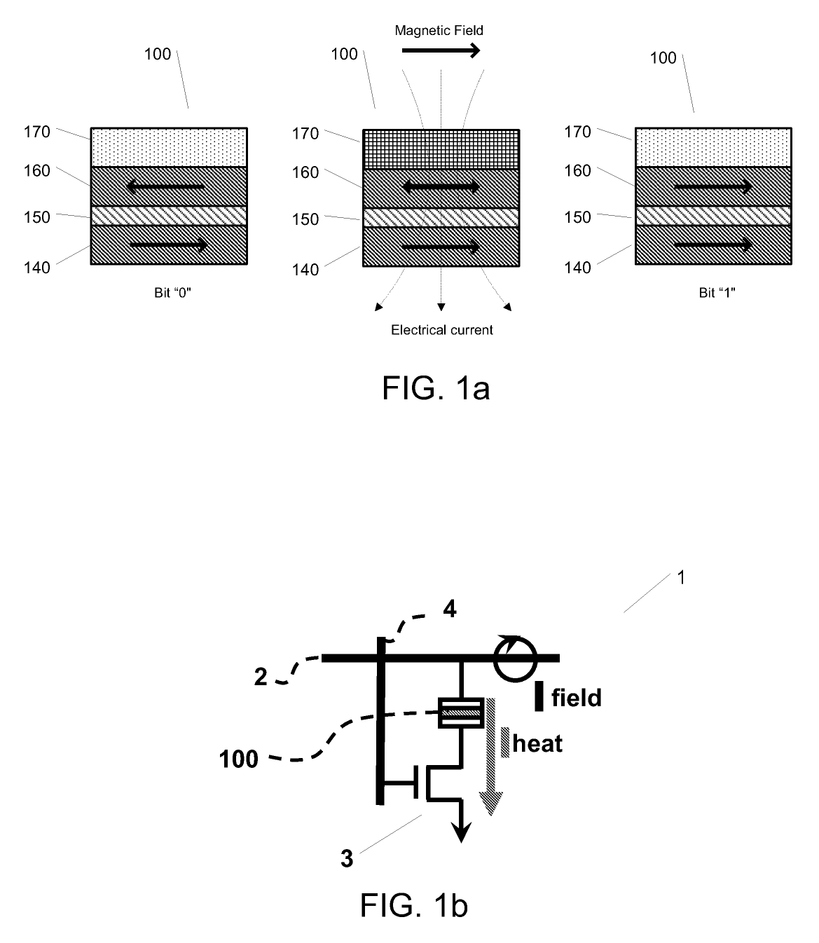

FIG. 1a is a schematic cross-sectional view of an integrated circuit having a magnetic device, including a thermally assisted MTJ element 100 according to one embodiment. In one embodiment, the magnetic tunnel junction (MTJ) stack 100 includes a reference layer structure 140 (also referred to as “fixed layer”), a tunneling insulating layer structure 150 disposed on or above the reference layer structure 140, a storage layer structure 160 of ferromagnetic (FM) material disposed on or above the tunneling insulating layer structure 150, and an antiferromagnetic layer structure 170 disposed on or above the ferromagnetic storage layer structure 160. In one embodiment, the antiferromagnetic material (AF) of the AF layer structure 170 is characterized by a blocking temperature (T_{B}) which is lower than the blocking temperature of the reference layer structure 140. In one embodiment, the blocking temperature is the temperature below which the antiferromagnetic layer structure 170 and the ferromagnetic storage layer structure 160 exhibit exchange bias. In one embodiment, the antiferromagnetic layer structure 170 exchange-biases the storage ferromagnetic layer structure 160.

In one embodiment, during a write operation, a pulse of current is sent through the MTJ stack 100, more precisely through the tunnel barrier layer 150, which is also used as a heating resistance. In one embodiment, by Joule's effect the MTJ element 100, and in particular, the storage layer structure 160 and the antiferromagnetic layer structure 170, are heated above the blocking temperature T_{B} of the antiferromagnetic material of the AFM layer structure 170 (but below the T_{B} of the reference layer structure 140) so that the pinning of the storage layer 160 vanishes, its magnetization direction being freed. In such a fashion, the storage layer 160 can be set by sufficiently small magnetic fields.

FIG. 1b is a schematic diagram illustrating an integrated circuit including a selected storage cell of an MRAM memory array, according to the architecture 1T1MTJ (1 Transistor 1 MTJ cell) 1, in accordance with the thermal select concept and according to one embodiment. In one embodiment, through a word line 4, a select transistor 3 is used to switch the local heating current through the insulating tunneling layer structure 150 of the MTJ cell 100. After the heat current is turned off, an adjacent bit line 2 current is used to generate the field required for setting the storage layer 160 orientation in the small time window before the AFM layer 170 gets too cool again. The structure is then cooled down under a magnetic field which is larger than the coercive field of the storage layer 160 at the write temperature. Once the structure is cooled down, the storage layer 160 remains pinned, making the data storage stable against thermal fluctuations of small dimensions. The magnetization directions of the different layer structures are represented by the arrows in FIG. 1a.

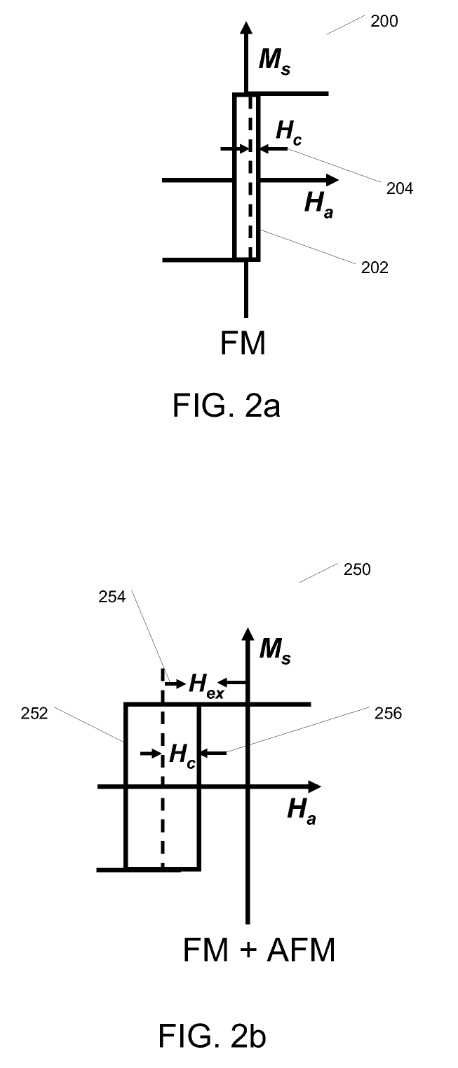

FIG. 2a and FIG. 2b are diagrams illustrating the exchange bias occurring between the antiferromagnetic layer structure 170 and the ferromagnetic storage layer structure 160 represented in FIG. 1b. In the diagram 200 of FIG. 2a, the hysteresis 202 of the ferromagnetic (FM) material shifted along the magnetic field axis before exchange bias is shown, H_{c} 204, representing the coercivity or the ease of switching the magnetic orientation of the memory cell. The diagram 250 of FIG. 2b shows an ideal hysteresis curve 252 of an easy axis direction for the produced exchange coupling layers. In the diagram 250, Hₑₓ 254 represents the exchanged bias magnetic or offset field and H_{c} 256 represents the coercivity or the ease of switching the magnetic orientation of the memory cell after exchange bias has occurred.

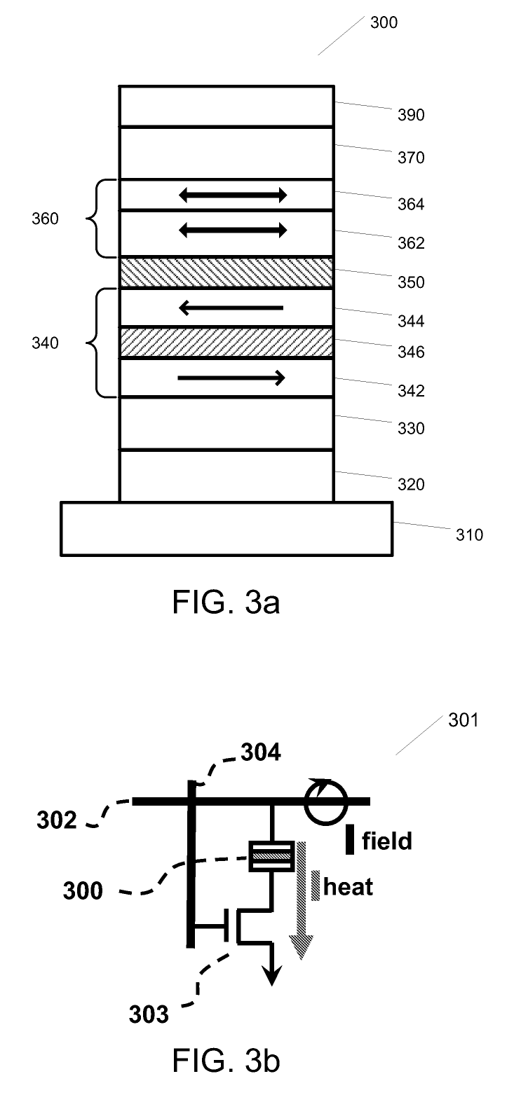

FIG. 3a is a schematic cross-sectional view illustrating one embodiment of a thermally assisted MTJ element. In one embodiment, the magnetic tunnel junction (MTJ) stack 300 includes a carrier 310 (e.g. a substrate), followed by the formation of a bottom conducting layer structure 320 (also referred to as “bottom lead layer”). In one embodiment, the conducting bottom layer structure 320 may be a multilayer formation of a Tantalum Nitride (TaN) layer and a Tantalum (Ta) layer deposited by sputter processes according to the sequence TaN-Ta (Ta layer formed above or on the TaN layer). In one embodiment, the Tantalum Nitride (TaN) layer may have an approximate thickness of 2 nanometers to 6 nanometers, while the Tantalum (Ta) layer may have an approximate thickness of 1 nanometer to 3 nanometers, although these ranges should be considered approximations and reasonable variations, due for example to manufacturing, can and should be expected.

In one embodiment, a bottom pinning layer structure of antiferromagnetic material (AFM) 330 is formed on or above the bottom conducting layer structure 320. In one embodiment, the pinning layer structure of antiferromagnetic material 330 may be a Platinum Manganese (PtMn) layer. In one embodiment, the bottom pinning AFM layer structure 330 layer may have an approximate thickness of 11 nanometers to 15 nanometers, although this range should be considered an approximation and reasonable variations, due for example to manufacturing, can and should be expected.

In one embodiment, a pinned layer structure termed “synthetic antiferromagnetic pinned layer” structure 340 (SyAP for brevity) is formed on or above the bottom AFM pinning layer structure 330. In one embodiment, the synthetic antiferromagnetic pinned (SyAP) layer structure 340 further comprises a first ferromagnetic layer structure 342, a coupling layer structure 346 disposed on or above the first ferromagnetic layer structure 342 and a second ferromagnetic layer structure 344 disposed on or above the coupling layer structure 346, the two ferromagnetic layer structures being subsequently magnetized in antiparallel directions with respect to each other as shown by the arrows in FIG. 3a during the annealing process.

In one embodiment, the first ferromagnetic layer structure 342 may include an amorphous magnetic layer of Cobalt Iron Boron (CoFeB) and a ferromagnetic layer of Cobalt Iron (CoFe) disposed on or above the amorphous magnetic layer of Cobalt Iron Boron (CoFeB). In one embodiment, the amorphous magnetic layer of Cobalt Iron Boron (CoFeB) has an approximate atom percentage of Boron (B) of 2% to 30%. In one embodiment, the amorphous magnetic layer of Cobalt Iron Boron (CoFeB) has an approximate atom percentage of Boron (B) of 13% to 25%. In one embodiment, the amorphous magnetic layer of Cobalt Iron Boron (CoFeB) has an approximate thickness of 0.5 nanometers to 1.5 nanometers. In one embodiment, the ferromagnetic layer of Cobalt Iron (CoFe) is approximately 30% Iron (Fe) by number of atoms and approximately 70% Cobalt (Co) by number of atoms. In one embodiment, the ferromagnetic layer of Cobalt Iron (CoFe) has an approximate thickness of 1.2 nanometers to 2.5 nanometers. These ranges should be considered an approximation and reasonable variations, due for example to manufacturing, can and should be expected.

In one embodiment, the first ferromagnetic layer structure 342 may include a first amorphous magnetic layer of Cobalt Iron Boron (CoFeB), a ferromagnetic layer of Cobalt Iron (CoFe) disposed on or above the first amorphous magnetic layer of Cobalt Iron Boron (CoFeB), and a second amorphous magnetic layer of Cobalt Iron Boron (CoFeB) disposed on or above the ferromagnetic layer of Cobalt Iron (CoFe). In one embodiment, the first amorphous magnetic layer of Cobalt Iron Boron (CoFeB) has an approximate atom percentage of Boron (B) of 2% to 30%. In one embodiment, the first amorphous magnetic layer of Cobalt iron Boron (CoFeB) has an approximate preferable atom percentage of Boron (B) of 13% to 25%. In one embodiment, the first amorphous magnetic layer of Cobalt Iron Boron (CoFeB) has an approximate thickness of 0.5 nanometers to 1.5 nanometers.

In one embodiment, the ferromagnetic Cobalt Iron (CoFe) layer is approximately 30% Iron (Fe) by number of atoms and approximately 70% Cobalt (Co) by number of atoms. In one embodiment, the ferromagnetic Cobalt Iron (CoFe) layer has an approximate thickness of 1.2 nanometers to 2.5 nanometers. In one embodiment the second amorphous magnetic layer of Cobalt Iron Boron (CoFeB) has an approximate atom percentage of Boron (B) of 2% to 20%.

In one embodiment, the second amorphous magnetic layer of Cobalt Iron Boron (CoFeB) has an approximate atom percentage of Boron (B) of 8% to 15%. In one embodiment, the second amorphous magnetic layer of Cobalt Iron Boron (CoFeB) has an approximate thickness of 0.1 nanometers to 0.39 nanometers. These ranges should be considered an approximation and reasonable variations, due for example to manufacturing, can and should be expected.

In one embodiment, the coupling layer structure 346 disposed on or above the first ferromagnetic pinned layer structure 342 of the synthetic antiferromagnetic pinned (SyAP) layer structure 340 comprises a Ruthenium (Ru) layer. In one embodiment, the coupling layer structure 346 of the synthetic antiferromagnetic pinned (SyAP) layer structure 340 has an approximate thickness of 0.81 nanometers to 0.89 nanometers. In one embodiment, the coupling layer structure 346 of the synthetic antiferromagnetic pinned (SyAP) layer structure 340 has an approximate preferable thickness of 0.85 nanometers. These ranges should be considered an approximation and reasonable variations, due for example to manufacturing, can and should be expected.

In one embodiment, the second ferromagnetic pinned layer structure 344 of the synthetic antiferromagnetic pinned (SyAP) 340 layer structure comprises an amorphous magnetic layer of Cobalt Iron Boron (CoFeB). In one embodiment, the amorphous magnetic layer of Cobalt Iron Boron (CoFeB) has an approximate atom percentage of Boron (B) of 2% to 30%. In one embodiment, the second ferromagnetic pinned layer structure 344 of the synthetic antiferromagnetic pinned (SyAP) layer structure 340 has an approximate thickness of 2 nanometers to 3.5 nanometers. These ranges should be considered an approximation and reasonable variations, due for example to manufacturing, can and should be expected.

In one embodiment, the second ferromagnetic pinned layer structure 344 of the synthetic antiferromagnetic pinned (SyAP) layer structure 340 comprises a first amorphous magnetic layer of Cobalt Iron Boron (CoFeB) and a second amorphous magnetic layer of Cobalt Iron Boron (CoFeB) disposed on or above the first amorphous magnetic layer of Cobalt Iron Boron. In one embodiment, the first amorphous magnetic layer of Cobalt Iron Boron (CoFeB) has an approximate atom percentage of Boron (B) of 2% to 30%. In one embodiment, the first amorphous magnetic layer of Cobalt Iron Boron (CoFeB) has an approximate preferable atom percentage of Boron (B) of 13% to 30%. In one embodiment, the first amorphous magnetic layer of Cobalt Iron Boron (CoFeB) has an approximate thickness of 1 nanometer to 3 nanometers. In one embodiment, the second amorphous magnetic layer of Cobalt Iron Boron (CoFeB) has an approximate atom percentage of Boron (B) of 2% to 30%. In one embodiment, the second amorphous magnetic layer of Cobalt Iron Boron (CoFeB) has an approximate preferable atom percentage of Boron (B) of 8% to 15%. In one embodiment, the second amorphous magnetic layer of Cobalt Iron Boron (CoFeB) has an approximate thickness of 0.1 nanometers to 0.39 nanometers. These ranges should be considered an approximation and reasonable variations, due for example to manufacturing, can and should be expected.

In one embodiment, an insulating tunnel layer structure 350 is formed on or above the synthetic antiferromagnetic pinned (SyAP) layer structure 340. In one embodiment, the insulating layer structure 350 comprises a Magnesium Oxide (MgO) layer. In one embodiment, the insulating layer structure 350 comprises a first metallic Magnesium (Mg) layer, a Magnesium Oxide (MgO) layer disposed on or above the first metallic Magnesium (Mg) layer, and a second metallic Magnesium (Mg) layer disposed on or above the Magnesium Oxide (MgO) layer. In one embodiment, the first metallic Magnesium (Mg) layer of the insulating layer structure 350 has an approximate thickness of 0.1 nanometers to 0.39 nanometers. In one embodiment, the second metallic Magnesium (Mg) layer of the insulating layer structure 350 has an approximate thickness of 0.1 nanometers to 0.39 nanometers. In one embodiment, the use of this method of fabricating the tunnel barrier layer of Magnesium Oxide (MgO) leads to very high Tunneling Magnetoresistance Ratio (TMR) and a Resistance Area product (RA) lower than 10 Ωμm². These ranges should be considered an approximation and reasonable variations, due for example to manufacturing, can and should be expected.

In one embodiment, a storage layer structure 360 is formed on or above the insulating layer structure 350, further comprising an amorphous magnetic layer 362 and a ferromagnetic layer 364 formed on the amorphous magnetic layer 362. In one embodiment, the amorphous magnetic layer 362 of the storage layer structure 360 comprises a Cobalt Iron Boron (CoFeB) layer. In one embodiment, the amorphous magnetic layer 362 of Cobalt Iron Boron (CoFeB) has an approximate atom percentage of Boron (B) of 2% to 30%. In one embodiment, the amorphous magnetic layer 362 of the storage layer structure 360 has an approximate thickness of 1.7 nanometers to 3.5 nanometers. In one embodiment, the ferromagnetic layer 364 of the storage layer structure 360 comprises a Nickel Iron (NiFe) layer. In one embodiment, the ferromagnetic layer 364 of Nickel Iron (NiFe) has an approximate atom percentage of Iron (Fe) of 19%. In one embodiment, the ferromagnetic layer 364 of the storage layer structure 360 has an approximate thickness of 1 nanometer to 3 nanometers. In another embodiment, the ferromagnetic layer 364 of Nickel Iron (NiFe) has an approximate preferable thickness of 1 nanometer to 2 nanometers. These ranges should be considered an approximation and reasonable variations, due for example to manufacturing, can and should be expected.

In one embodiment, an upper antiferromagnetic layer structure 370 is formed on or above the storage layer structure 360. In one embodiment, the upper antiferromagnetic layer structure 370 comprises an Iridium Manganese (IrMn) layer. In one embodiment, the upper antiferromagnetic layer structure 370 of Iridium Manganese (IrMn) has an approximate atom percentage of Iridium (Jr) of 20% to 30%, the Iridium Manganese (IrMn) alloy being also represented by the general formula IrₓMn₁₀₀₋ₓ, where x represents a value by atomic % satisfying the expression 20≦x≦30. In one embodiment, the upper antiferromagnetic layer structure 370 has an approximate thickness of 1.5 nanometers to 4 nanometers. These ranges should be considered an approximation and reasonable variations, due for example to manufacturing, can and should be expected.

In one embodiment, the antiferromagnetic material (AF) of the upper antiferromagnetic layer structure 370 is characterized by a blocking temperature (T_{B}) which is lower than the blocking temperature of the bottom pinning layer structure 330. The blocking temperature is the temperature below which the upper antiferromagnetic layer structure 370 and the storage layer structure 360 exhibit exchange bias. In one embodiment, the upper antiferromagnetic layer structure 370 exchange-biases the storage layer structure 360, the upper antiferromagnetic layer structure 370 and the storage layer structure 360 forming an exchange biasing film. In one embodiment, the upper antiferromagnetic layer structure 370 shows an exchange bias field on continuous film at room temperature higher than 100 Oersted (Oe), wherein the blocking temperatures of the upper antiferromagnetic layer structure 370 for both continuous and nanostructure films are approximately between 120° C. and 230° C.

In one embodiment, a top conductive layer structure 390 is formed on the upper antiferromagnetic layer structure 370. In one embodiment, the top conductive layer structure 390 comprises a Tantalum Nitride (TaN) layer. In one embodiment, the top conductive layer structure 390 has an approximate thickness of 5 nanometers to 15 nanometers. These ranges should be considered an approximation and reasonable variations, due for example to manufacturing, can and should be expected.

In one embodiment, during a write operation, a pulse of current is sent through the MTJ stack 300, more precisely through the insulating tunneling layer structure 350, which is also used as a heating resistance. In one embodiment, by Joule's effect the MTJ element 300, and in particular the storage layer structure 360 and the upper antiferromagnetic layer structure 370 are heated above the blocking temperature T_{B} of the antiferromagnetic material of the upper antiferromagnetic layer structure 370 (but below the T_{B} of the bottom pinning layer structure 330) so that the pinning of the storage layer structure 360 vanishes, its magnetization direction being freed; in this way the storage layer structure 360 can be set by sufficiently small magnetic fields.

FIG. 3b is a schematic diagram illustrating the operation of a memory architecture 1T1MTJ (1 Transistor 1 MTJ cell) 301 according to one embodiment. In one embodiment, through a word line 304, a select transistor 303 is used to switch the local heating current through the insulating tunneling layer structure 350 of the MTJ cell 300. After the heat current is turned off, an adjacent bit line 302 current is used to generate the field required for setting the storage layer structure 360 orientation in the small time window before the upper antiferromagnetic layer structure 370 gets too cool again. The structure is then cooled down under a magnetic field, larger than the coercive field of the storage layer structure 360 at the write temperature. Once the structure is cooled down, the storage layer structure 360 remains pinned, making the data storage stable against thermal fluctuations of small dimensions. The magnetization directions of the different layer structures are represented by the arrows in FIG. 3a.

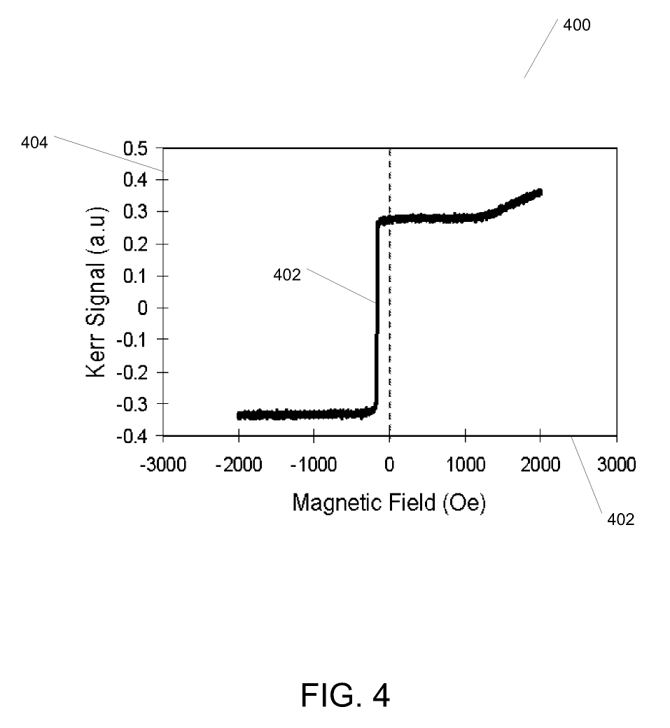

FIG. 4 is a graph illustrating an example of a hysteresis loop 402 for an MTJ element at room temperature according to one embodiment. In diagram 400 of FIG. 4, there is also described an example of the exchange bias occurring between the storage layer structure 360 and the upper antiferromagnetic layer structure 370 as illustrated in FIG. 3. In the example illustrated by FIG. 4, according to one embodiment, the amorphous magnetic layer 362 of Cobalt Iron Boron (CoFeB) has an approximate thickness of 2 nanometers, the ferromagnetic layer 364 of Nickel Iron (NiFe) has an approximate thickness of 1.5 nanometers and the upper antiferromagnetic layer structure 370 of Iridium Manganese (IrMn) has an approximate thickness of 3 nanometers, with Iridium Manganese (IrMn) processed at 80 sccm (Standard Cubic Centimeters per Minute) of Argon (Ar) flow. The Kerr signal 404, as a function of the magnetic field 402, clearly shows that a high exchange bias or offset magnetic field of about 170 Oersted (Oe) is obtained at room temperature after annealing at 280° C., for approximately 2 hours of soaking time in a 10 kOe magnetic field. The curves are offset for clarity (a.u., arbitrary units).

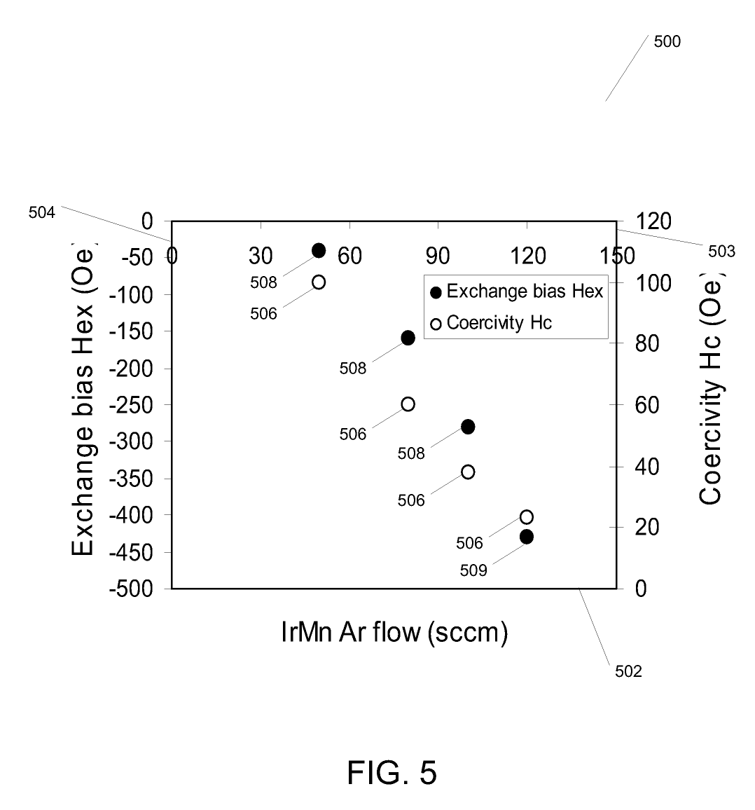

FIG. 5 is a diagram 500 illustrating, the exchange bias Hₑₓ 504 and the coercivity H, 503 as a function of the different Argon (Ar) deposition process conditions for IrMn 502 according to one embodiment. There are shown different values of the exchange bias Hₑₓ 508 at room temperature occurring between the storage layer structure 360 and the upper antiferromagnetic layer structure 370 (as illustrated in FIG. 3) using different Argon (Ar) deposition process conditions for IrMn according to one embodiment of the invention. FIG. 5 shows that the highest exchange bias Hₑₓ 504 (e.g. 509) at room temperature is obtained with an Argon (Ar) flow for IrMn of about 120 sccm (Standard Cubic Centimeters per Minute). This is the highest Hₑₓ 504 at room temperature obtained with an Iridium Manganese IrMn thickness of approximately 3 nanometers. A decrease in the coercivity Hc 503 (e.g. 506) is also noted.

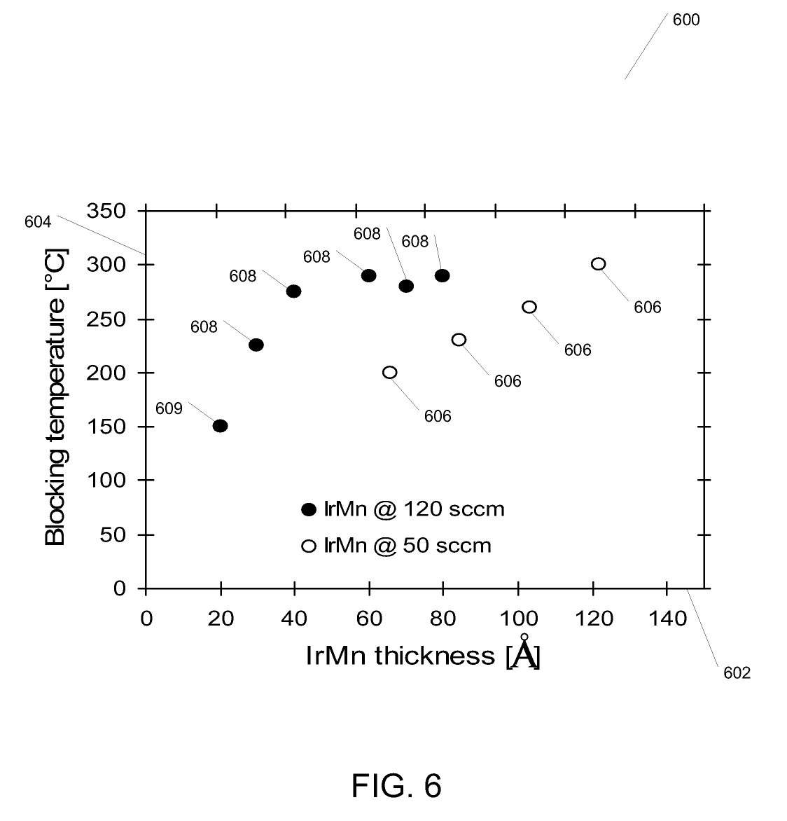

FIG. 6 is a diagram 600 illustrating the blocking temperature 604 of the exchanged coupling storage layer structure 360 and the upper antiferromagnetic layer structure 370 (as illustrated in FIG. 3) as a function of the thickness of the Iridium Manganese (IrMn) layer 602 expressed in Angstroms (A) for two Argon process flows—IrMn at 120 sccm (e.g. 608 and 609) and IrMn at 50 sccm (e.g 606)—according to different embodiments. Diagram 600 of FIG. 6 clearly shows that, according to one embodiment, the Iridium Manganese (IrMn) layer of the upper antiferromagnetic layer structure 370 processed at 120 sccm (Standard Cubic Centimeters per Minute) of Argon (Ar) flow has practical blocking temperatures for both continuous and nanostructure films between 120° C. and 230° C. (e.g. 609)—compatible with the blocking temperatures according to the thermally assisted MRAM concept (150° C.-180° C.)—and shows high exchange bias for IrMn layer thickness of approximately 1.5 nanometers to 4 nanometers.

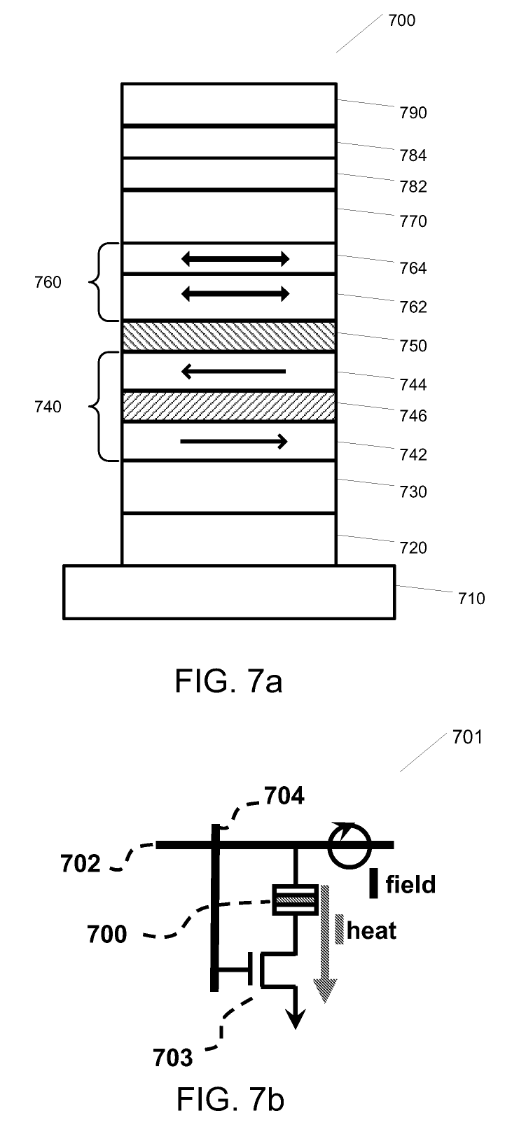

FIG. 7a is a schematic cross-sectional view illustrating one embodiment of a thermally assisted MTJ element. The magnetic tunnel junction (MTJ) stack 700 includes a carrier 710 (e.g. a substrate), followed by the formation of a bottom conducting layer structure 720 (also referred to as “bottom lead layer”). In one embodiment, the conducting bottom layer structure 720 may be a multilayer formation of a Tantalum Nitride (TaN) layer and a Tantalum (Ta) layer deposited by sputter processes according to the sequence TaN-Ta (Ta layer formed above or on the TaN layer). In one embodiment, the Tantalum Nitride (TaN) layer may have an approximate thickness of 2 nanometers to 6 nanometers, while the Tantalum (Ta) layer may have an approximate thickness of 1 nanometer to 3 nanometers, although these ranges should be considered approximations and reasonable variations, due for example to manufacturing, can and should be expected.

In one embodiment, a bottom pinning layer structure of antiferromagnetic material (AFM) 730 is formed on or above the bottom conducting layer structure 720. In one embodiment, the pinning layer structure of antiferromagnetic material may be a Platinum Manganese (PtMn) layer. In one embodiment, the bottom conducting layer structure 720 layer may have an approximate thickness of 11 nanometers to 15 nanometers, although this range should be considered an approximation and reasonable variations, due for example to manufacturing, can and should be expected.

In one embodiment, a pinned layer structure termed “synthetic antiferromagnetic pinned layer” structure 740 (SyAP for brevity) is formed on or above the bottom AFM pinning layer structure 730. In one embodiment, the synthetic antiferromagnetic pinned (SyAP) layer structure 740 further comprises a first ferromagnetic layer structure 742, a coupling layer structure 746 disposed on or above the first ferromagnetic layer structure 742 and a second ferromagnetic layer structure 744 disposed on or above the coupling layer structure 746, the two ferromagnetic layer structures being subsequently magnetized in antiparallel directions with respect to each other as shown by the arrows in FIG. 7a during the annealing process.

In one embodiment, the first ferromagnetic layer structure 742 may include an amorphous magnetic layer of Cobalt Iron Boron (CoFeB) and a ferromagnetic layer of Cobalt Iron (CoFe) disposed on or above the amorphous magnetic layer of Cobalt Iron Boron (CoFeB). In one embodiment, the amorphous magnetic layer of Cobalt Iron Boron (CoFeB) has an approximate atom percentage of Boron (B) of 2% to 30%. In one embodiment, the amorphous magnetic layer of Cobalt Iron Boron (CoFeB) has an approximate preferable atom percentage of Boron (B) of 13% to 25%. In one embodiment, the amorphous magnetic layer of Cobalt Iron Boron (CoFeB) has an approximate thickness of 0.5 nanometers to 1.5 nanometers. In one embodiment, the ferromagnetic layer of Cobalt Iron (CoFe) is approximately 30% Iron (Fe) by number of atoms and approximately 70% Cobalt (Co) by number of atoms. In one embodiment, the ferromagnetic layer of Cobalt Iron (CoFe) has an approximate thickness of 1.2 nanometers to 2.5 nanometers. These ranges should be considered an approximation and reasonable variations, due for example to manufacturing, can and should be expected.

In one embodiment, the first ferromagnetic layer structure 742 may include first amorphous magnetic layer of Cobalt Iron Boron (CoFeB), a ferromagnetic layer of Cobalt Iron (CoFe) disposed on or above the first amorphous magnetic layer of Cobalt Iron Boron (CoFeB) and a second amorphous magnetic layer of Cobalt Iron Boron (CoFeB) disposed on or above the ferromagnetic layer of Cobalt Iron (CoFe). In one embodiment, the first amorphous magnetic layer of Cobalt Iron Boron (CoFeB) has an approximate atom percentage of Boron (B) of 2% to 30%. In one embodiment, the first amorphous magnetic layer of Cobalt iron Boron (CoFeB) has an approximate preferable atom percentage of Boron (B) of 13% to 25%. In one embodiment, the first amorphous magnetic layer of Cobalt Iron Boron (CoFeB) has an approximate thickness of 0.5 nanometers to 1.5 nanometers. In one embodiment, the ferromagnetic Cobalt Iron (CoFe) layer is approximately 30% Iron (Fe) by number of atoms and approximately 70% Cobalt (Co) by number of atoms. In one embodiment, the ferromagnetic Cobalt Iron (CoFe) layer has an approximate thickness of 1.2 nanometers to 2.5 nanometers. In one embodiment the second amorphous magnetic layer of Cobalt Iron Boron (CoFeB) has an approximate atom percentage of Boron (B) of 2% to 20%. In one embodiment, the second amorphous magnetic layer of Cobalt Iron Boron (CoFeB) has an approximate preferable atom percentage of Boron (B) of 8% to 15%. In one embodiment, the second amorphous magnetic layer of Cobalt Iron Boron (CoFeB) has an approximate thickness of 0.1 nanometers to 0.39 nanometers. These ranges should be considered an approximation and reasonable variations, due for example to manufacturing, can and should be expected.

In one embodiment, the coupling layer structure 746 disposed on or above the first ferromagnetic pinned layer structure 742 of the synthetic antiferromagnetic pinned (SyAP) layer structure 740 comprises a Ruthenium (Ru) layer. In one embodiment, the coupling layer structure 746 of the synthetic antiferromagnetic pinned (SyAP) layer structure 740 has an approximate thickness of 0.81 nanometers to 0.89 nanometers. In one embodiment, the coupling layer structure 746 of the synthetic antiferromagnetic pinned (SyAP) layer structure 740 has an approximate preferable thickness of 0.85 nanometers. These ranges should be considered an approximation and reasonable variations, due for example to manufacturing, can and should be expected.

In one embodiment, the second ferromagnetic pinned layer structure 744 of the synthetic antiferromagnetic pinned (SyAP) 740 layer structure comprises an amorphous magnetic layer of Cobalt Iron Boron (CoFeB). In one embodiment, the amorphous magnetic layer of Cobalt Iron Boron (CoFeB) has an approximate atom percentage of Boron (B) of 2% to 30%. In one embodiment, the second ferromagnetic pinned layer structure 744 of the synthetic antiferromagnetic pinned (SyAP) layer structure 740 has an approximate thickness of 2 nanometers to 3.5 nanometers. These ranges should be considered an approximation and reasonable variations, due for example to manufacturing, can and should be expected.

In one embodiment, the second ferromagnetic pinned layer structure 744 of the synthetic antiferromagnetic pinned (SyAP) layer structure 740 comprises a first amorphous magnetic layer of Cobalt Iron Boron (CoFeB) and a second amorphous magnetic layer of Cobalt Iron Boron (CoFeB) disposed on or above the first amorphous magnetic layer of Cobalt Iron Boron. In one embodiment, the first amorphous magnetic layer of Cobalt Iron Boron (CoFeB) has an approximate atom percentage of Boron (B) of 2% to 30%. In one embodiment, the first amorphous magnetic layer of Cobalt Iron Boron (CoFeB) has an approximate preferable atom percentage of Boron (B) of 13% to 30%. In one embodiment, the first amorphous magnetic layer of Cobalt Iron Boron (CoFeB) has an approximate thickness of 1 nanometer to 3 nanometers. In one embodiment, the second amorphous magnetic layer of Cobalt Iron Boron (CoFeB) has an approximate atom percentage of Boron (B) of 2% to 30%. In one embodiment, the second amorphous magnetic layer of Cobalt Iron Boron (CoFeB) has an approximate preferable atom percentage of Boron (B) of 8% to 15%. In one embodiment, the second amorphous magnetic layer of Cobalt Iron Boron (CoFeB) has an approximate thickness of 0.1 nanometers to 0.39 nanometers. These ranges should be considered an approximation and reasonable variations, due for example to manufacturing, can and should be expected.

In one embodiment, an insulating tunnel layer structure 750 is formed on or above the synthetic antiferromagnetic pinned (SyAP) layer structure 740. In one embodiment, the insulating layer structure 750 comprises a Magnesium Oxide (MgO) layer. In one embodiment, the insulating layer structure 750 comprises a first metallic Magnesium (Mg) layer, a Magnesium Oxide (MgO) layer disposed on or above the first metallic Magnesium (Mg) layer, and a second metallic Magnesium (Mg) layer disposed on or above the Magnesium Oxide (MgO) layer. In one embodiment, the first metallic Magnesium (Mg) layer of the insulating layer structure 750 has an approximate thickness of 0.1 nanometers to 0.39 nanometers. In one embodiment, the second metallic Magnesium (Mg) layer of the insulating layer structure 750 has an approximate thickness of 0.1 nanometers to 0.39 nanometers. In one embodiment, the use of this method of fabricating the tunnel barrier layer of Magnesium Oxide (MgO) leads to very high Tunneling Magnetoresistance Ratio (TMR) and a Resistance Area product (RA) lower than 10 Ωμm². These ranges should be considered an approximation and reasonable variations, due for example to manufacturing, can and should be expected.

In one embodiment, a storage layer structure 760 is formed on or above the insulating layer structure 750, further comprising an amorphous magnetic layer 762 and a ferromagnetic layer 764 formed on the amorphous magnetic layer 762. In one embodiment, the amorphous magnetic layer 762 of the storage layer structure 760 comprises a Cobalt Iron Boron (CoFeB) layer. In one embodiment, the amorphous magnetic layer 762 of Cobalt Iron Boron (CoFeB) has an approximate atom percentage of Boron (B) of 2% to 30%. In one embodiment, the amorphous magnetic layer 762 of the storage layer structure 760 has an approximate thickness of 1.7 nanometers to 3.5 nanometers. In one embodiment, the ferromagnetic layer 764 of the storage layer structure 760 comprises a Nickel Iron (NiFe) layer. In one embodiment, the ferromagnetic layer 764 of Nickel Iron (NiFe) has an approximate atom percentage of Iron (Fe) of 19%. In one embodiment, the ferromagnetic layer 764 of the storage layer structure 760 has an approximate thickness of 1 nanometer to 3 nanometers. In another embodiment, the ferromagnetic layer 764 of Nickel Iron (NiFe) has an approximate preferable thickness of 1 nanometer to 2 nanometers. These ranges should be considered an approximation and reasonable variations, due for example to manufacturing, can and should be expected.

In one embodiment, an upper antiferromagnetic layer structure 770 is formed on or above the storage layer structure 760. In one embodiment, the upper antiferromagnetic layer structure 770 comprises an Iridium Manganese (IrMn) layer. In one embodiment, the upper antiferromagnetic layer structure 770 of Iridium Manganese (IrMn) has an approximate atom percentage of Iridium (Ir) of 20% to 30%, the Iridium Manganese (IrMn) alloy being also represented by the general formula IrₓMn₁₀₀₋ₓ, where x represents a value by atomic % satisfying the expression 20≦x≦30. In one embodiment, the upper antiferromagnetic layer structure 770 has an approximate thickness of 1.5 nanometers to 4 nanometers. These ranges should be considered an approximation and reasonable variations, due for example to manufacturing, can and should be expected.

In one embodiment, the antiferromagnetic material (AF) of the upper antiferromagnetic layer structure 770 is characterized by a blocking temperature (T_{B}) which is lower than the blocking temperature of the bottom pinning layer structure 730. The blocking temperature is the temperature below which the upper antiferromagnetic layer structure 770 and the storage layer structure 760 exhibit exchange bias. In one embodiment, the upper antiferromagnetic layer structure 770 exchange-biases the storage layer structure 760, the upper antiferromagnetic layer structure 770 and the storage layer structure 760 forming an exchange biasing film. In one embodiment, the upper antiferromagnetic layer structure 770 shows an exchange bias field on continuous film at room temperature higher than 100 Oersted (Oe), wherein the blocking temperatures of the upper antiferromagnetic layer structure 770 for both continuous and nanostructure films is approximately between 120° C. and 230° C.

In one embodiment, a first etch stop layer structure 782 is formed on or above the upper antiferromagnetic layer structure 770. In one embodiment, the first etch stop layer structure 782 includes a Tantalum (Ta) layer. In one embodiment, the first etch stop layer structure 782 has an approximate thickness of 1 nanometer to 2 nanometers. In one embodiment, a second etch stop layer structure 784 is formed on or above the first etch stop layer structure 782. In one embodiment, the second etch stop layer structure 784 includes a Nickel Iron (NiFe) layer. In one embodiment, the second etch stop layer structure 784 of Nickel Iron (NiFe) has an approximate atom percentage of Iron (Fe) of 19%. In one embodiment, the second etch stop layer structure 784 has an approximate thickness of 0.8 nanometers to 1.5 nanometers. The first etch stop layer structure 782 and the second etch stop layer structure 784 are etch stop layers used for patterning and have no effect on the exchange bias Hₑₓ and the blocking temperatures of the MTJ element 700.

In one embodiment, a top conductive layer structure 790 is formed on or above the second etch stop layer structure 784. In one embodiment, the top conductive layer structure 790 comprises a Tantalum Nitride (TaN) layer. In one embodiment, the top conductive layer structure 790 has an approximate thickness of 5 nanometers to 15 nanometers.

In one embodiment, during the write operation, a pulse of current is sent through the MTJ stack 700, more precisely through the insulating tunneling layer structure 750 also used as a heating resistance. In one embodiment, by Joule's effect the MTJ element 700, and in particular the storage layer structure 760 and the upper antiferromagnetic layer structure 770 are heated above the blocking temperature T_{B} of the antiferromagnetic material of the upper antiferromagnetic layer structure 770 (but below the T_{B} of the bottom pinning layer structure 730) so that the pinning of the storage layer structure 760 vanishes, its magnetization direction being freed; in this way the storage layer structure 760 can be set by sufficiently small magnetic fields.

FIG. 7b is a schematic diagram illustrating a selected storage cell of an MRAM memory array, according to the architecture 1T1MTJ (1 Transistor 1 MTJ cell) 701, in accordance with the thermal select concept and according to one embodiment. In one embodiment, through a word line 704 a select transistor 703 is used to switch the local heating current through the insulating tunneling layer structure 750 of the MTJ cell 700, while (after the heat current is turned off) an adjacent bit line 702 current is used to generate the field required for setting the storage layer structure 760 orientation in the small time window before the upper antiferromagnetic layer structure 770 gets too cool again. The structure is then cooled down under a magnetic field, larger than the coercive field of the storage layer structure 760 at the write temperature. Once the structure is cooled down, the storage layer structure 760 remains pinned, making the data storage stable against thermal fluctuations of small dimensions. The magnetization directions of the different layer structures are represented by the arrows in FIG. 7a.

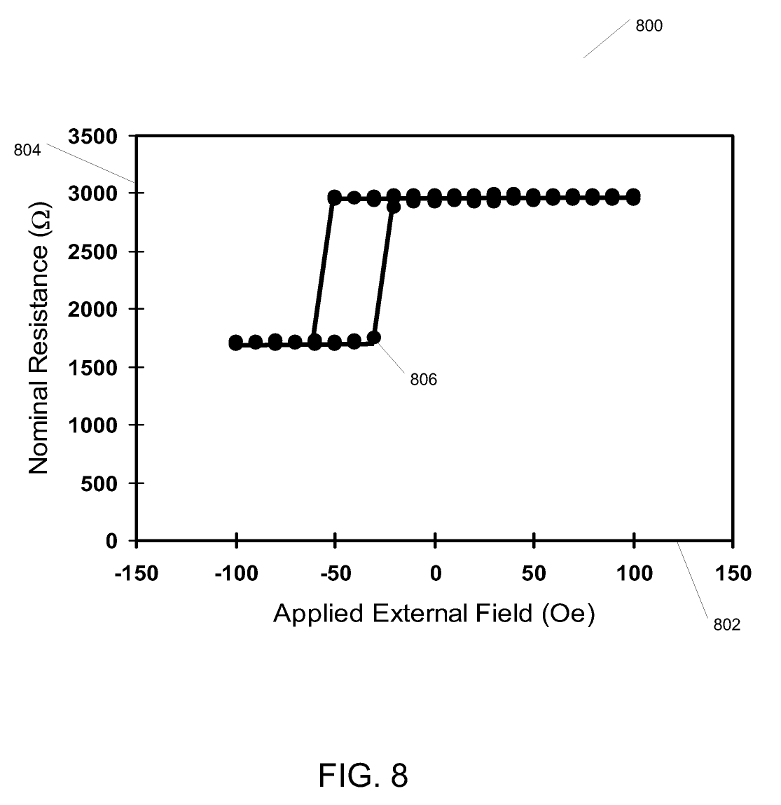

FIG. 8 is a diagram 800 illustrating an example of a hysteresis loop 806 of a 400×600 nm² patterned MTJ cell 700 according to one embodiment, measured at room temperature for a bias voltage of −1350 millivolts (mV). The nominal resistance 804 expressed in Ohm (Ω) is shown as a function of the applied external field 802 expressed in Oersted (Oe). It is clearly seen the good symmetry of the hysteresis loop and the switching of the cell between state “0” and state “1” corresponding, respectively to parallel and antiparallel states at low fields (<45 Oe). This good symmetry of the loop clearly demonstrates the effectiveness of the MTJ element, the method of forming it and the method of programming it as described in the embodiments of the invention, for the thermal select concept.

According to another embodiment, the MTJ element, the method of forming it, and the method of programming it as described in the embodiments can also apply to the thermally assisted spin torque concept.

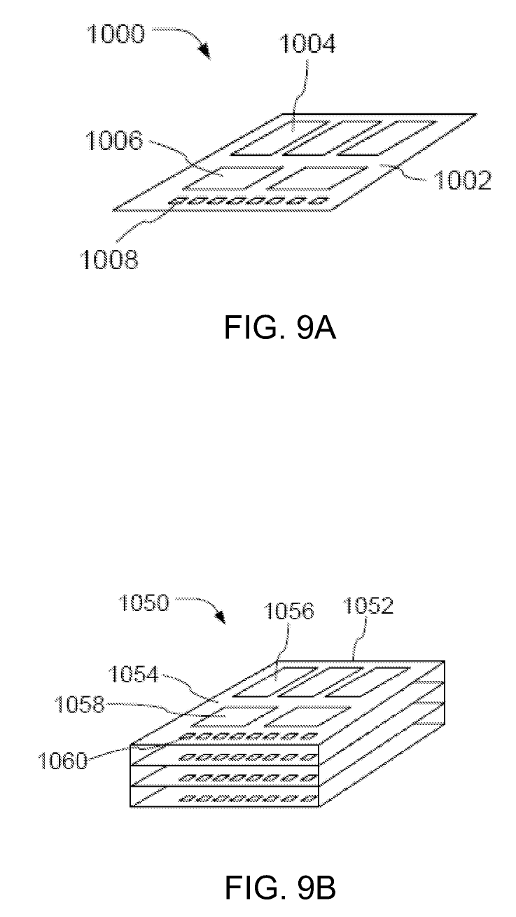

As shown in FIGS. 9A and 9B, in some embodiments, memory devices comprising magnetic tunnel junctions, such as those described herein, may be used in modules. FIG. 9A is a schematic diagram illustrating one embodiment of a memory module 1000 on which one or more memory devices 1004 are arranged on a substrate 1002. The memory device 1004 may include numerous memory cells, each of which uses a memory element in accordance with an embodiment of the invention (e.g. including the magnetic tunnel junction 700). The memory module 1000 may also include one or more electronic devices 1006, which may include memory, processing circuitry, control circuitry, addressing circuitry, bus interconnection circuitry, or other circuitry or electronic devices that may be combined on a module with a memory device, such as the memory device 1004. Additionally, the memory module 1000 includes multiple electrical connections 1008, which may be used to connect the memory module 1000 to other electronic components, including other modules.

As illustrated by FIG. 9B, in some embodiments, these modules may be stackable, to form a stack 1050. For example, a stackable memory module 1052 may contain one or more memory devices 1056, arranged on a stackable substrate 1054. The memory device 1056 contains memory cells that employ memory elements in accordance with an embodiment of the invention. The stackable memory module 1052 may also include one or more electronic devices 1058, which may include memory, processing circuitry, control circuitry, addressing circuitry, bus interconnection circuitry, or other circuitry or electronic devices that may be combined on a module with a memory device, such as the memory device 1056. Electrical connections 1060 are used to connect the stackable memory module 1052 with other modules in the stack 1050, or with other electronic devices. Other modules in the stack 1050 may include additional stackable memory modules, similar to the stackable memory module 1052 described above, or other types of stackable modules, such as stackable processing modules, control modules, communication modules, or other modules containing electronic components.

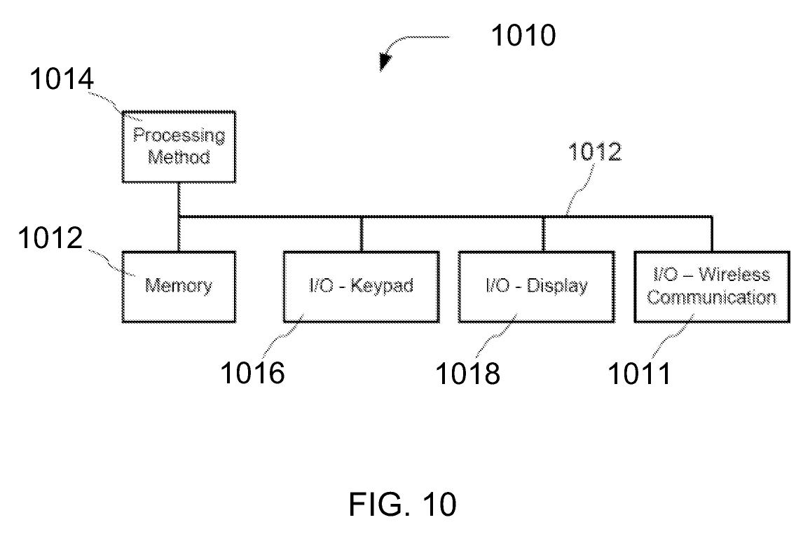

In accordance with some embodiments of the invention, memory devices that include memory elements as described herein may be used in a variety of other applications or systems, such as the example computing system illustrated schematically by FIG. 10. The computing system 1010 includes a memory device 1012, which may include memory elements comprising magnetic tunnel junctions in accordance with an embodiment of the invention (e.g. including the magnetic tunnel junction 700). The system also includes processing method 1014, such as a microprocessor or other processing device or controller, and one or more input/output functionalities or devices, such as a keypad 1016, display 1018, and wireless communication method 1011. The memory device 1012, processing method 1014, keypad 1016, display 1018 and wireless communication device 1011 are interconnected by a bus 1012.

The wireless communication method 1011 may have the ability to send and/or receive transmissions over a cellular telephone network, a WiFi wireless network, or other wireless communication network. It will be understood that the input/output devices, functionalities, and/or methods shown in FIG. 10 are merely examples. Memory devices including memory cells comprising magnetic tunnel junctions in accordance with embodiments of the invention may be used in a variety of systems. Alternative systems may include a variety input/output devices, functionalities, and/or methods, multiple processors or processing methods, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied.

All embodiments described above can be included, for example, in hard disk drives, computers systems, notebooks, sensor systems (e.g. spin valve sensors in read heads), computer displays and cellular phones.

All embodiments described above can be included, for example, in magnetic read heads for hard disk drives, computers systems, notebooks, sensor systems (e.g. spin valve sensors in read heads), computer displays and cellular phones.

Additionally, all embodiments described above are valid not only for an MTJ device, but also for the method of programming the MTJ device, for the method of forming the MTJ device, and for an MRAM array including the MTJ device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a magnetic device comprising:
a reference structure having a first blocking temperature;
a storage structure made of a ferromagnetic material; and
an antiferromagnetic structure having a second blocking temperature lower than the first blocking temperature.

2. The integrated circuit of claim 1 comprising:
where the second blocking temperature is defined as a temperature below which the antiferromagnetic structure and the storage structure exhibit exchange bias.

3. The integrated circuit of claim 1 comprising:
where the antiferromagnetic structure is configured to exchange-bias the storage structure.

4. The integrated circuit of claim 1 comprising:
a tunnel barrier disposed on or above the reference layer.

5. The integrated circuit of claim 1 comprising:
a heater, where upon application of a current the heater is configured to heat the storage structure and the antiferromagnetic structure to a temperature above the second blocking temperature, and below the first blocking temperature obviating pinning of the storage structure.

6. The integrated circuit of claim 5 comprising:
the heater comprising a barrier.

7. The integrated circuit of claim 6 where the barrier comprises an insulating layer.

8. The integrated circuit of claim 1 comprising:
where the antiferromagnetic structure is located on or above the storage structure.

9. An integrated circuit having a magnetic device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the first and second ferromagnetic pinned layer structures magnetized in antiparallel directions with respect to each other;
an insulating layer structure disposed above the synthetic antiferromagnetic pinned layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure; and
a top conductive layer structure disposed above the upper antiferromagnetic layer structure.

10. The magnetic integrated circuit junction device of claim 9, wherein the bottom conductive layer structure comprises a Tantalum Nitride (TaN) layer and a Tantalum (Ta) layer disposed above the Tantalum Nitride (TaN) layer.

11. The magnetic integrated circuit junction device of claim 10, wherein the Tantalum Nitride (TaN) layer has an approximate thickness of 2 to 6 nanometers and an approximate thickness of 1 to 3 nanometer.

12. The magnetic integrated circuit junction device of claim 9, wherein the bottom pinning layer structure comprises a Platinum Manganese (PtMn) layer.

13. The magnetic integrated circuit junction device of claim 9, wherein the bottom pinning layer structure has an approximate thickness of 11 to 15 nanometers.

14. The magnetic integrated circuit junction device of claim 9, wherein the first ferromagnetic pinned layer structure of the synthetic antiferromagnetic pinned (SyAP) layer structure comprises an amorphous magnetic layer of Cobalt Iron Boron (CoFeB) and a ferromagnetic layer of Cobalt Iron (CoFe) disposed above the amorphous magnetic layer of Cobalt Iron Boron (CoFeB).

15. The magnetic integrated circuit junction device of claim 14, wherein the amorphous magnetic layer of Cobalt Iron Boron (CoFeB) has an approximate atom percentage of Boron (B) of 2% to 30% and an approximate thickness of 0.5 nanometers to 1.5 nanometers.

16. The magnetic integrated circuit junction device of claim 14, wherein the ferromagnetic Cobalt Iron (CoFe) layer is approximately 30% Iron (Fe) by number of atoms and an approximate thickness of 1.2 nanometers to 2.5 nanometers.

17. The magnetic integrated circuit junction device of claim 9, wherein the first ferromagnetic layer structure of the synthetic antiferromagnetic pinned (SyAP) layer structure comprises a first amorphous magnetic layer of Cobalt Iron Boron (CoFeB), a ferromagnetic layer of Cobalt Iron (CoFe) disposed above the first amorphous magnetic layer of Cobalt Iron Boron (CoFeB), and a second amorphous magnetic layer of Cobalt Iron Boron (CoFeB) disposed above the ferromagnetic layer of Cobalt Iron (CoFe).

18. The magnetic integrated circuit junction device of claim 17, wherein the first amorphous magnetic layer of Cobalt Iron Boron (CoFeB) has an approximate atom percentage of Boron (B) of 2% to 30%, and an approximate thickness of 0.5 nanometers to 1.5 nanometers.

19. The magnetic integrated circuit junction device of claim 17, wherein the ferromagnetic Cobalt Iron (CoFe) layer is approximately 30% Iron (Fe) by number of atoms, and an approximate thickness of 1.2 nanometers to 2.5 nanometers.

20. The magnetic integrated circuit junction device of claim 17, wherein the second amorphous magnetic layer of Cobalt Iron Boron (CoFeB) has an approximate atom percentage of Boron (B) of 2% to 30%, and an approximate thickness of 0.1 nanometers to 0.39 nanometers.

21. The magnetic integrated circuit junction device of claim 9, wherein the coupling layer structure of the synthetic antiferromagnetic pinned layer structure comprises a Ruthenium (Ru) layer.

22. The magnetic integrated circuit junction device of claim 9, wherein the coupling layer structure of the synthetic antiferromagnetic pinned layer structure has an approximate thickness of 0.81 nanometers to 0.89 nanometers.

23. The magnetic integrated circuit junction device of claim 9, wherein the second ferromagnetic pinned layer structure of the synthetic antiferromagnetic pinned layer structure comprises an amorphous magnetic layer of Cobalt Iron Boron (CoFeB).

24. The magnetic integrated circuit junction device of claim 23, wherein the amorphous magnetic layer of Cobalt Iron Boron (CoFeB) has an approximate atom percentage of Boron (B) of 2% to 30%.

25. The magnetic integrated circuit junction device of claim 9, wherein the second ferromagnetic pinned layer structure of the synthetic antiferromagnetic pinned layer structure has an approximate thickness of 2 nanometers to 3.5 nanometers.

26. The magnetic integrated circuit junction device of claim 9, wherein the second ferromagnetic pinned layer structure of the synthetic antiferromagnetic pinned layer structure comprises a first amorphous magnetic layer of Cobalt Iron Boron (CoFeB) and a second amorphous magnetic layer of Cobalt Iron Boron (CoFeB) disposed above the first amorphous magnetic layer of Cobalt Iron Boron.

27. The magnetic integrated circuit junction device of claim 26, wherein the first amorphous magnetic layer of Cobalt Iron Boron (CoFeB) has an approximate atom percentage of Boron (B) of 2% to 30% and an approximate thickness of 1 nanometer to 3 nanometers.

28. The magnetic integrated circuit junction device of claim 26, wherein the second amorphous magnetic layer of Cobalt Iron Boron (CoFeB) has an approximate atom percentage of Boron (B) of 2% to 30% and an approximate thickness of 0.1 nanometers to 0.39 nanometers.

29. The magnetic integrated circuit junction device of claim 9, wherein the insulating layer structure comprises a Magnesium Oxide (MgO) layer.

30. The magnetic integrated circuit junction device of claim 9, wherein the insulating layer structure comprises a first metallic Magnesium (Mg) layer, a Magnesium Oxide (MgO) layer disposed above the first metallic Magnesium (Mg) layer, and a second metallic Magnesium (Mg) layer disposed above the Magnesium Oxide (MgO) layer.

31. The magnetic integrated circuit junction device of claim 30, wherein the first and second metallic Magnesium (Mg) layers of the insulating layer structure each have an approximate thickness of 0.1 nanometers to 0.39 nanometers.

32. The magnetic integrated circuit junction device of claim 9, wherein the storage layer structure comprises an amorphous magnetic layer of Cobalt iron Boron (CoFeB) and a ferromagnetic layer of Nickel Iron (NiFe) disposed on or above the amorphous magnetic layer of Cobalt iron Boron (CoFeB).

33. The magnetic integrated circuit junction device of claim 32, wherein the amorphous magnetic layer of Cobalt Iron Boron (CoFeB) has an approximate atom percentage of Boron (B) of 2% to 30% and an approximate thickness of 1.7 nanometers to 3.5 nanometers.

34. The magnetic integrated circuit junction device of claim 32, wherein the ferromagnetic layer of Nickel Iron (NiFe) has an approximate atom percentage of Iron (Fe) of 19%, and an approximate thickness of 1 nanometer to 3 nanometers.

35. The magnetic integrated circuit junction device of claim 9, wherein the upper antiferromagnetic layer structure comprises an Iridium Manganese (IrMn) layer.

36. The magnetic integrated circuit junction device of claim 35, wherein the upper antiferromagnetic layer structure of Iridium Manganese (IrMn) has an approximate atom percentage of Iridium (Jr) of 20% to 30% and an approximate thickness of 1.5 nanometers to 4 nanometers.

37. The magnetic integrated circuit junction device of claim 9, wherein the top conductive layer structure comprises a Tantalum Nitride (TaN) layer.

38. The magnetic integrated circuit junction device of claim 9, wherein the top conductive layer structure has an approximate thickness of 5 nanometers to 15 nanometers.

39. The magnetic integrated circuit junction device of claim 9, wherein the upper antiferromagnetic layer structure and the storage layer structure form an exchange biasing film.

40. The magnetic integrated circuit junction device of claim 9, wherein the upper antiferromagnetic layer structure has a blocking temperature lower than a blocking temperature of the antiferromagnetic material of the bottom pinning layer structure.

41. The magnetic integrated circuit junction device of claim 9, wherein the upper antiferromagnetic layer structure shows an exchange bias field on continuous film at room temperature higher than 100 Oe, and wherein blocking temperatures of the upper antiferromagnetic layer structure for both continuous and nanostructure films is approximately between 120° C. and 230° C.

42. The magnetic integrated circuit junction device of claim 9, further comprising:
a first etch stop layer structure disposed above the upper antiferromagnetic layer structure; and
a second etch stop layer structure disposed above the first etch stop layer structure and below the top conductive layer structure.

43. The magnetic integrated circuit junction device of claim 42, wherein the first etch stop layer structure includes a Tantalum (Ta) layer.

44. The magnetic integrated circuit junction device of claim 42, wherein the first etch stop layer structure has an approximate thickness of 1 nanometer to 2 nanometers.

45. The magnetic integrated circuit junction device of claim 42, wherein the second etch stop layer structure includes a Nickel Iron (NiFe) layer.

46. The magnetic integrated circuit junction device of claim 45, wherein second etch stop layer structure of Nickel Iron (NiFe) has an approximate atom percentage of Iron (Fe) of 19%.

47. The magnetic integrated circuit junction device of claim 42, wherein the second etch stop layer has an approximate thickness of 0.8 nanometers to 1.5 nanometers.

48. A method of forming an integrated circuit having a magnetic integrated circuit junction device comprising:
providing a carrier;
forming a bottom conductive layer structure above the carrier;
forming a bottom pinning layer structure of antiferromagnetic material above the bottom conducting layer structure;
forming a synthetic antiferromagnetic pinned layer structure above the bottom pinning layer structure, comprising: forming a first ferromagnetic pinned layer structure, forming a coupling layer structure above the first ferromagnetic pinned layer structure and a second ferromagnetic pinned layer structure above the coupling layer, the two ferromagnetic pinned layer structures magnetized in antiparallel directions with respect to each other;
forming an insulating layer structure above the synthetic antiferromagnetic pinned layer structure;
forming a storage layer structure above the insulating layer structure comprising: forming an amorphous magnetic layer and a ferromagnetic layer above the amorphous magnetic layer;
forming an upper antiferromagnetic layer structure above the storage layer structure; and
forming a top conductive layer structure above the upper antiferromagnetic layer structure.

49. An array of thermally assisted magnetic random access memory structures, each of the magnetic memory structures comprising:
a magnetic tunnel junction device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the two ferromagnetic pinned layer structures magnetized in antiparallel directions with respect to each other;
an insulating layer structure disposed above the synthetic antiferromagnetic pinned (SyAP) layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure; and
a top conductive layer structure disposed above the upper antiferromagnetic layer structure;
a write conductor contacting and selecting the magnetic tunnel junction device, and
a heating system contacting the magnetic tunnel junction device and heating the storage layer structure of the magnetic tunnel junction device above the blocking temperature of the antiferromagnetic material of the upper antiferromagnetic layer structure but below the blocking temperature of the bottom pinning layer structure.

50. A magnetic read head device comprising:
a magnetic tunnel junction device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the two ferromagnetic pinned layer structures magnetized in antiparallel directions with respect to each other;
an insulating layer structure disposed above the synthetic antiferromagnetic pinned (SyAP) layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure; and
a top conductive layer structure disposed above the upper antiferromagnetic layer structure.

51. A computing system comprising:
an input apparatus;
an output apparatus;
a processing apparatus; and
a memory element, the memory element comprising:
a magnetic tunnel junction device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the two ferromagnetic pinned layer structures magnetized in antiparallel directions with respect to each other;
an insulating layer structure disposed above the synthetic antiferromagnetic pinned layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure;
a top conductive layer structure disposed above the upper antiferromagnetic layer structure.

52. The computing system of claim 51, wherein at least one of the input apparatus and the output apparatus comprises a wireless communication apparatus.

53. A memory module comprising:
a magnetic tunnel junction device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the two ferromagnetic pinned layer structures magnetized in antiparallel directions with respect to each other;
an insulating layer structure disposed above the synthetic antiferromagnetic pinned layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure; and
a top conductive layer structure disposed above the upper antiferromagnetic layer structure.

54. The memory module of claim 53, wherein the memory module is stackable.

55. A sensor system comprising:
a magnetic tunnel junction device comprising:
a carrier;
a bottom conductive layer structure disposed above the carrier;
a bottom pinning layer structure of antiferromagnetic material disposed above the bottom conducting layer structure;
a synthetic antiferromagnetic pinned layer structure disposed above the bottom pinning layer structure, comprising: a first ferromagnetic pinned layer structure, a coupling layer structure disposed above the first ferromagnetic pinned layer structure and a second ferromagnetic pinned layer structure disposed above the coupling layer, the two ferromagnetic pinned layer structures magnetized in antiparallel directions with respect to each other;
an insulating layer structure disposed above the synthetic antiferromagnetic pinned layer structure;
a storage layer structure disposed above the insulating layer structure comprising an amorphous magnetic layer and a ferromagnetic layer disposed above the amorphous magnetic layer;
an upper antiferromagnetic layer structure disposed above the storage layer structure;
a top conductive layer structure disposed above the upper antiferromagnetic layer structure.
